(19) United States
(12) Patent Application Publication
(10) Pub. No.: US 2012/0132266 A1
(43) Pub. Date: May 31, 2012

(54) PHOTOELECTRIC CONVERSION DEVICE USING SEMICONDUCTOR NANOMATERIAL

(75) Inventors: Joon-Dong KIM, Daejeon-city (KR); Chang-Soo Han, Daejeon-city (KR); Eung-Sug Lee, Daejeon-city (KR); Byung-Ik Choi, Daejeon-city (KR); Kyung-Hyun Whang, Daejeon-city (KR)

(73) Assignee: Korea Institute of Machinery & Materials, Yuseong-gu (KR)

(21) Appl. No.: 13/309,318

(22) Filed: Dec. 1, 2011

Related U.S. Application Data
(63) Continuation-in-part of application No. 12/209,493, filed on Sep. 12, 2008, now abandoned.

(30) Foreign Application Priority Data
Apr. 2, 2008 (KR) 10-2008-0030951

(51) Int. Cl. H01L 31/07; B82Y 99/00

(52) U.S. Cl. 136/255; 977/948

(57) ABSTRACT

Provided is a photoelectric conversion device using a semiconductor nanomaterial, which converts light energy having photon energy into electrical energy, including: a substrate, a plurality of semiconductor nanomaterials arranged on the substrate, and a metal layer that is formed on the semiconductor nanomaterial and is joined with the semiconductor nanomaterial by a schottky junction, wherein electrical energy is generated by a rectified current generated between the semiconductor nanomaterial and the metal layer joined by the schottky junction.

### CROSS-REFERENCE TO RELATED APPLICATIONS

This application is a continuation-in-part of U.S. Ser. No. 12/209,493 filed Sep. 12, 2008, and claims the benefit of priority from Korean Patent Application No. 10-2008-0030951 filed Apr. 2, 2008, the entire contents of which are incorporated herein by reference.

### BACKGROUND OF THE INVENTION

(a) Field of the Invention

The present invention relates to a photoelectric conversion device, and particularly, to a photoelectric conversion device using a semiconductor nanomaterial, to which a rectifying action by a schottky junction between a semiconductor nanomaterial and metal is applied.

(b) Description of the Related Art

Since a solar cell that is a photoelectric conversion device converting light having photon energy such as solar light into electrical energy is infinite and environmentally-friendly unlike other energy sources, an importance thereof is growing over time.

Particularly, if the solar cell is installed in various portable information devices such as a portable computer, a portable phone, and a personal portable terminal, it is expected that charging is feasible by only solar light.

As a known solar cell, a single crystal or polycrystal silicon wafer type solar cell that is a first generation of the solar cell has been mainly used, but the silicon wafer type solar cell causes a high manufacturing cost because a large and expensive equipment is used when the solar cell is manufactured and a cost of raw material is high, and has many difficulties in improving efficiency converting the solar energy into electrical energy.

Thereafter, a second generation thin film solar cell substitutes use of the silicon wafer and is commercialized in a thin film form that consumes a small amount of silicon.

In addition, recently, as a third generation solar cell that can be manufactured in a low cost, an interest for a solar cell using an organic material is rapidly growing, and particularly, a dye sensitive solar cell manufactured in a low cost is keenly watched.

FIG. 1 is a schematic diagram of a p-n junction semiconductor solar cell.

Referring to FIG. 1, the solar cell is formed of a p-n junction structure that joins a p-type semiconductor 110 and an n-type semiconductor 120, an antireflection (AR) layer 130 for decreasing a reflection loss of light, a front surface contact electrode 140, and a rear surface contact electrode 150.

If the semiconductor absorbs light (photon) by a photoelectric effect because of a characteristic of the semiconductor, free electrons and holes are generated, and in a general semiconductor, photon energy absorbed while the free electrons and holes are recombined is converted into phonon energy such as heat, but in the solar cell, since positions of the free electrons and holes around the p-n junction are exchanged because of an electronic field around the p-n junction and an electric potential is formed, when a diode is connected to the outside of the solar cell, a current resultantly flows.

That is, as shown in FIG. 2, if light is incident on the solar cell, light is absorbed into the solar cell, and holes and electrons are generated from energy of the absorbed light and freely move in the solar cell, but the electrons move toward the N-type semiconductor and the holes are moved toward the P-type semiconductor, such that a potential occurs.

In addition, if a load is connected between an electrode 140 that is contacted with a side of the N-type semiconductor and an electrode 150 that is joined to a side of the P-type semiconductor, a electricity flows, which is a basic principle of power generation by the pn junction of the solar cell.

However, this photoelectric conversion device has a drawback in that since a reflection ratio of light incident from the outside is high and a reabsorption ratio thereof is low, efficiency of power generation of solar light is low.

In addition, since an expensive large area substrate should be used, a manufacturing cost is high, in the case where a P-type substrate is used, doping of an N-type that is an opposite type should be performed, and in the case where an N-type substrate is used, doping of a P-type that is an opposite type should be performed, such that there is a drawback in that a process is cumbersome.

In addition, in order to decrease a reflection ratio of incident light in a known art, a texturing process for forming pyramid type protrusions and depressions on a surface of a substrate is performed, which is a drawback of increasing process steps.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a photoelectric conversion device using a semiconductor nanomaterial, which induces a electricity flow by generating a flow of electron-hole when solar light is incident by a work function different between a semiconductor nanomaterial and a metal joined therewith by a schottky junction by arranging the semiconductor nanomaterial on a substrate and constituting a metal layer forming the schottky junction with the nanomaterial.

An exemplary embodiment of the present invention provides a photoelectric conversion device using a semiconductor nanomaterial, which converts light energy having photon energy into electrical energy, the device including a substrate, a plurality of semiconductor nanomaterials arranged on the substrate, and a metal layer that is formed on the semiconductor nanomaterial and is joined with the semiconductor nanomaterial by a schottky junction, wherein electrical energy is generated by a rectified current generated between the semiconductor nanomaterial and the metal layer joined by the schottky junction.

Insulating layers may be formed on the substrate, the semiconductor nanomaterial may be arranged between the insulating layers, and a nanomaterial layer in which the semiconductor nanomaterials are horizontally arranged may be formed between the substrate and the metal layer.

An insulating layer for preventing a carrier generated by light from being recombined may be formed between the nanomaterial layer and the metal layer, and the substrate may be formed of a conductive substrate and may be used as a rear surface junction electrode.

On an upper portion of one side of the semiconductor nanomaterial, a junction electrode that is formed of a metal material forming an ohmic junction with the semiconductor nanomaterial may be formed, and the junction electrode and the metal layer may be arranged side by side.

The metal layer may be formed of platinum, the junction electrode may be formed of aluminum, and the semiconductor nanomaterial may be formed of a nanowire, and the metal layer may be formed of a transparent conductive oxide.

The semiconductor nanomaterial may be formed of a semiconductor nanoprotrusion, and the metal layer may be formed of a transparent metal film covering the semiconductor nanoprotrusion, and the substrate may have a P-type semiconductor layer and an N-type semiconductor layer joined with the P-type semiconductor layer by a PN junction.

The semiconductor nanoprotrusion may be formed by etching the substrate, and a front surface electrode formed of the transparent conductive oxide may be formed on the semiconductor nanoprotrusion.

The semiconductor nanomaterial may be an N-type semiconductor, a work function of the semiconductor nanomaterial may be smaller than a work function of the metal layer, the semiconductor nanomaterial may be a P-type semiconductor, and a work function of the semiconductor nanomaterial may be larger than a work function of the metal layer.

According to the exemplary embodiment of the present invention, there is an advantage in that since additional doping and texturing processes are not performed by generating a electricity flow by inducing an electron-hole flow by solar light by a difference between work functions of a semiconductor nanomaterial and a metal layer that are joined by a schottky junction without a separate p-n junction, a process can be simplified.

Further, there are advantages in that constituent elements and processes are simplified by using a conductive substrate as a rear surface junction electrode, or using a metal layer as a front surface junction electrode.

In addition, there is an advantage in that since a reflection ratio of light is decreased and a reabsorption ratio thereof is increased by repeatedly reflecting and reabsorbing light between vertical arranged nanomaterials, efficiency of generating electrical energy can be improved.

### BRIEF DESCRIPTION OF THE DRAWINGS

FIG. 1 is a schematic diagram of a general p-n junction semiconductor solar cell that is an example of a photoconversion device.

FIG. 2 is a schematic diagram illustrating a power generation principle by a pn junction of a photoelectric conversion device.

FIG. 3 is a cross-sectional view of a photoelectric conversion device using a semiconductor nanomaterial according to a first exemplary embodiment of the present invention.

FIG. 4 and FIG. 5 are reference views for explaining an operation of the present invention.

FIG. 6 is a cross-sectional view of a photoelectric conversion device using a semiconductor nanomaterial according to a second exemplary embodiment of the present invention.

FIG. 7 is a cross-sectional view of a photoelectric conversion device using a semiconductor nanomaterial according to a third exemplary embodiment of the present invention.

FIG. 8 is a cross-sectional view of a photoelectric conversion device using a semiconductor nanomaterial according to a fourth exemplary embodiment of the present invention.

FIG. 9A is a view illustrating a relationship of work functions of a metal layer and a semiconductor nanomaterial, and FIG. 9B is a view illustrating a relationship of work functions of the metal layer and semiconductor nanomaterial.

FIGS. 10A to 10c are pictures illustrating a photoelectric conversion device manufactured according to an exemplary variation of the fourth exemplary embodiment of the present invention.

FIG. 11 is a current voltage diagram of the photoelectric conversion device according to the exemplary variation of the fourth exemplary embodiment of the present invention.

FIG. 12 is a cross-sectional view of a photoelectric conversion device according to a fifth exemplary embodiment of the present invention.

FIG. 13 is a perspective view illustrating the photoelectric conversion device according to the fifth exemplary embodiment of the present invention.

FIG. 14A is a picture illustrating that a transparent electrode is formed on a silicon wafer, FIG. 14B is a picture illustrating that a transparent metal film and the transparent electrode are formed on a low density nanoprotrusion, and FIG. 14C is a picture illustrating that the transparent metal film and the transparent electrode are formed on a high density nanoprotrusion.

FIG. 15A is a cross-sectional view obtained by cutting the photoelectric conversion device according to the first exemplary embodiment of the present invention in a length direction, FIG. 15B is a picture in which an inside of a quadrangle in FIG. 15A is enlarged, and FIG. 15C is a picture in which an interface between the nanoprotrusion and transparent metal film is enlarged.

FIG. 16A is a graph illustrating a component profile between the nanoprotrusions in a horizontal direction with respect to an upper surface of a silicon wafer according to the first exemplary embodiment of the present invention, FIG. 16B is a graph illustrating a component profile in a depth direction of the silicon wafer according to the first exemplary embodiment of the present invention, and FIG. 16C is a graph illustrating a component profile in a depth direction of the silicon wafer in a state in which an AZO electrode is formed on a flat wafer.

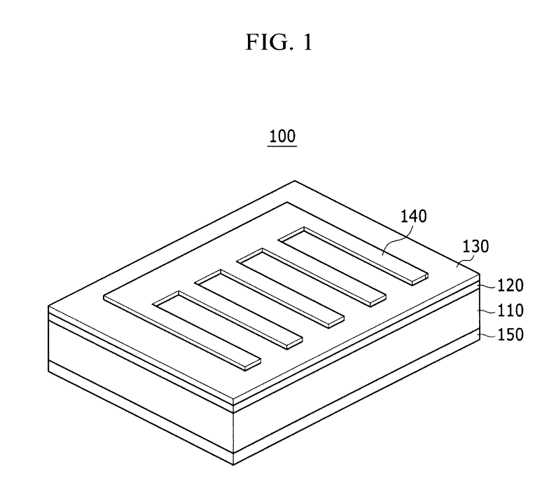

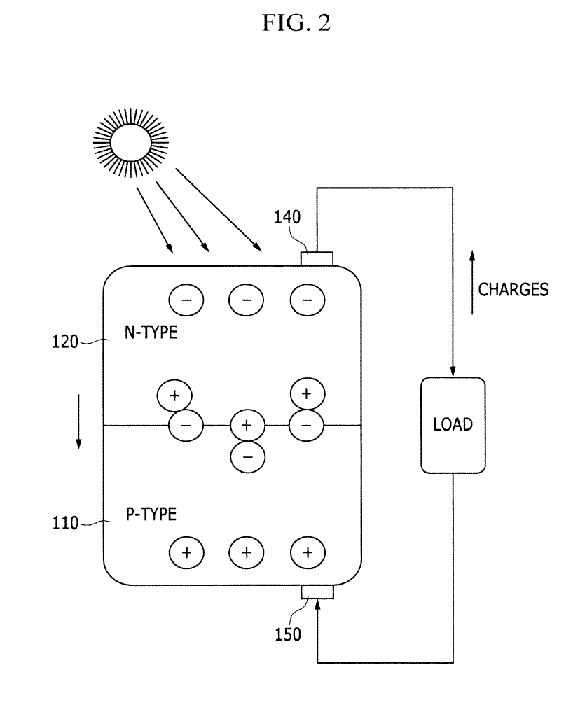

### DETAILED DESCRIPTION OF THE EMBODIMENTS

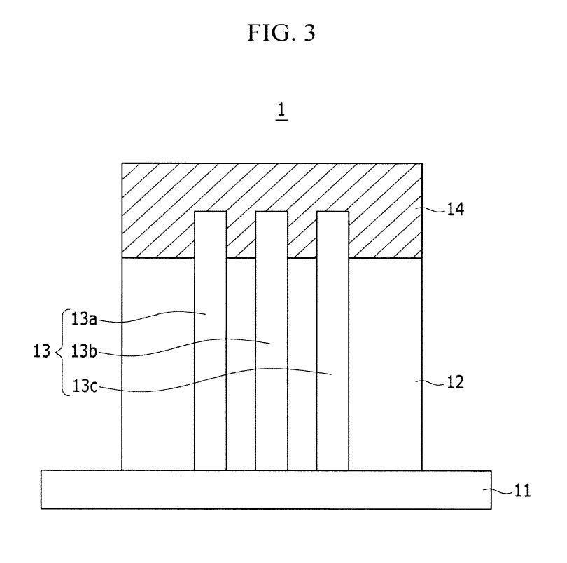

FIG. 3 is a cross-sectional view of a photoelectric conversion device using a semiconductor nanomaterial according to a first exemplary embodiment of the present invention, and the present invention relates to a photoelectric conversion device for converting light energy having photon energy into electrical energy.

Referring to FIG. 3, a photoelectric conversion device 1 according to the first exemplary embodiment of the present invention includes a substrate 11, an insulating layer 12, a semiconductor nanomaterial layer 13, and a metal layer 14.

Herein, the substrate 11 may be a conductive substrate, and in the case where the substrate has conductivity, the substrate 11 acts as a rear surface junction electrode.

Further, the insulating layer 12 may act as a support layer of the semiconductor nanomaterial layer 13, and may act as an antireflection film made of a transparent material such as SiO₂, and SiN having a large insulating coefficient.

In addition, the semiconductor nanomaterial layer 13 is vertically arranged between the insulating layers 12, and constituted by a plurality of semiconductor nanomaterials 13a, 13b, and 13c having a semiconductor characteristic. Therefore, the semiconductor nanomaterials 13a, 13b, and 13c are installed so that lower ends are contacted with the substrate 11 and upper ends are contacted with the metal layer 14.

The semiconductor nanomaterials 13a, 13b, and 13c may be formed of a nanowire, and particularly, may be formed of a silicon nanowire or a germanium nanowire.

Further, the semiconductor nanomaterials 13a, 13b, and 13c may be formed of at least one selected from a Group 4 intrinsic semiconductor, a Group 4-4 compound semiconductor, a Group 3-5 compound semiconductor, a Group 2-6 compound semiconductor and a Group 4-6 compound semiconductor, and a characteristic thereof may be changed through separate doping or junction.

The semiconductor nanomaterial layer 13 may be vertically arranged by imprinting or etching the substrate that is formed of the semiconductor nanomaterials 13a, 13b, and 13c.

The metal layer 14 is joined with the semiconductor nanomaterials 13a, 13b, and 13c by the schottky junction on the upper portion of the semiconductor nanomaterial layer 13. The metal layer 14 may be made of aluminum (Al) or platinum (Pt). In the case where the metal layer 14 is made of an opaque material such as aluminum and platinum, the metal layer is formed in a small thickness enough to transmit light. Accordingly, the thickness of the metal layer may be 1 nm to 30 nm.

Further, the metal layer 14 may be made of a transparent conductive oxide (TCO) that can transmit light. In this case, the metal layer 14 may be formed of indium-tin-oxide (ITO), Al-doped zinc oxide (AZO), Zn-doped indium oxide (IZO), MgO, Nb:SrTiO3, Ga-doped ZnO (GZO), Nb-doped TiO2, (La0.5Sr0.5)CoO3 (LSCO), La0.7Sr0.3MnO3 (LSMO), SrRuO3 (SRO), F-doped tin oxide, Sr3Ru2O7, or Sr4Ru3O10.

According to the characteristic aspect of the present invention, electrical energy is generated by a rectification current generated between the semiconductor nanomaterials 13a, 13b, and 13c and metal layer 14 that are joined by the schottky junction.

That is, when light having photon energy is incident between the semiconductor nanomaterials 13a, 13b, and 13c and metal layer 14 that are joined by the schottky junction, the electron and hole are moved in opposite directions, such that a rectifying type current is formed.

Accordingly, in the present invention, in order to obtain a cell energy by an electron-hole flow between the semiconductor nanomaterials 13a, 13b, and 13c and metal layer 14, in the case where the N-type semiconductor nanomaterial is used, the work function (Φs) of the semiconductor nanomaterial should be smaller than the work function (Φm) of the metal layer 14, and in the case where the P-type semiconductor nanomaterial is used, the work function (Φs) should be larger than the work function (Φm) of the metal layer 14.

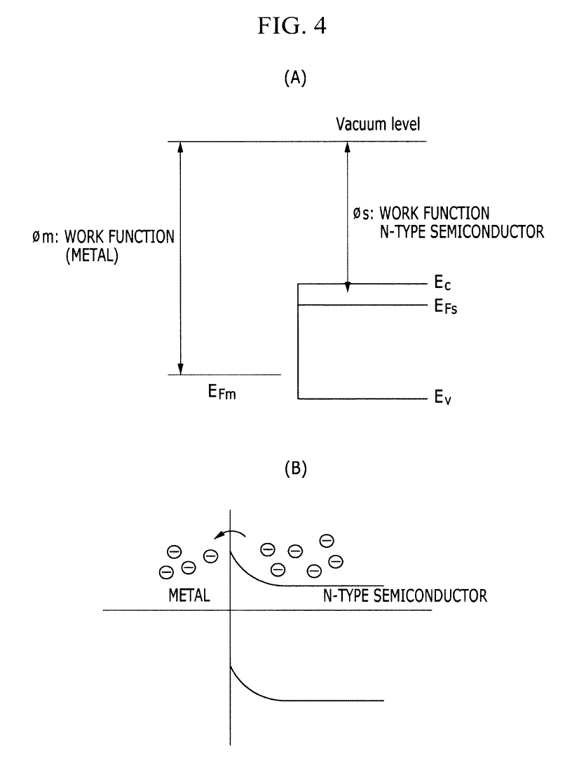

That is, as shown in FIG. 4, if the work function (Φs) of the N-type semiconductor is smaller than the work function (Φm) of the metal layer 14, the electrons of the N-type semiconductor nanomaterial are moved in a direction of the metal layer 14, and the holes are moved in an opposite direction, such that a potential barrier is formed. In this case, if light is incident, the electrons and holes are separated, the electrons are moved to the N-type semiconductor nanomaterial, and the holes are moved to the metal layer 14, such that a voltage difference occurs.

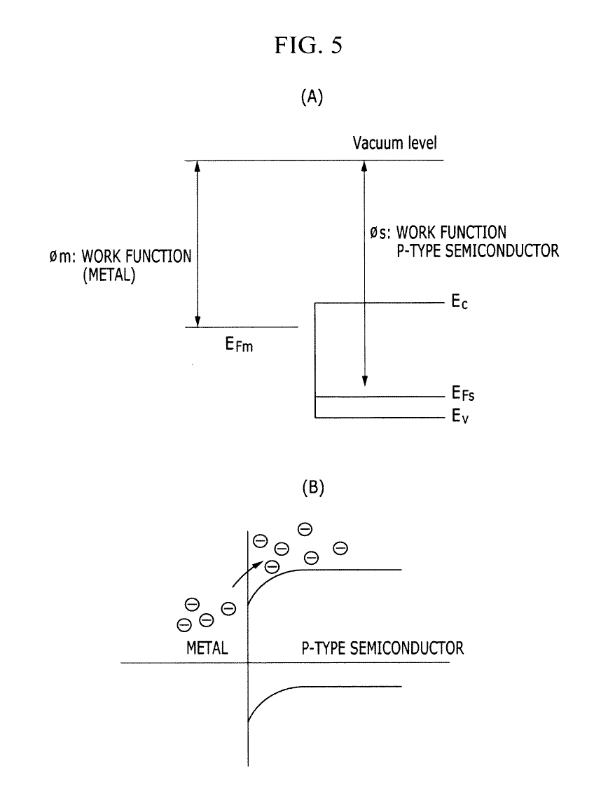

Further, as shown in FIG. 5, if the work function (Φs) of the P-type semiconductor is larger than the work function (Φm) of the metal layer 14, as shown in FIG. 5B, the electrons of the metal layer are moved in a direction of the N-type semiconductor nanomaterial, and the holes are moved in an opposite direction, such that a potential barrier is formed. In this case, if light is incident, the electrons and holes are separated, the electrons are moved to the metal layer, and the holes are moved to the P-type semiconductor nanomaterial, such that a voltage difference occurs.

In addition, in the photoelectric conversion device using a known p-n junction, a separate front surface junction metal is further included, but in the first exemplary embodiment of the present invention, the metal layer 14 may be used as the front surface junction electrode.

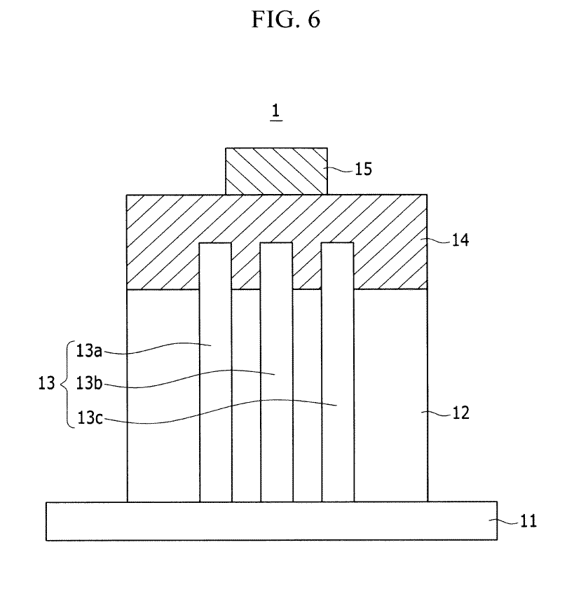

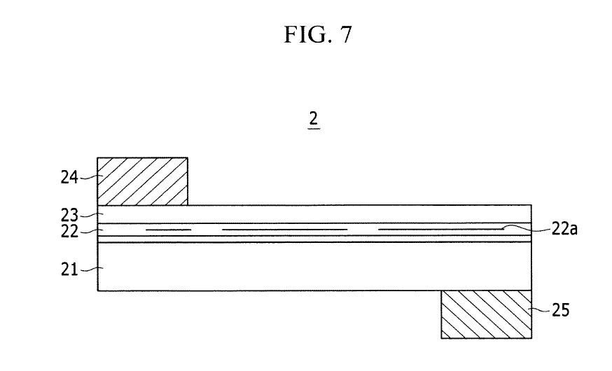

FIG. 6 is a cross-sectional view of a photoelectric conversion device using a semiconductor nanomaterial according to a second exemplary embodiment of the present invention, and the detailed operation description with respect to the same constituent elements as the first exemplary embodiment of the present invention will be omitted.

Referring to FIG. 6, the second exemplary embodiment of the present invention includes a substrate 11, an insulating layer 12, a semiconductor nanomaterial layer 13, a metal layer 14, and a front surface junction electrode 15, and an operation for generating an electricity flow is the same as the first exemplary embodiment.

Herein, the front surface junction electrode 15 and the metal layer 14 form an ohmic junction.

According to the first exemplary embodiment and the second exemplary embodiment of the present invention, a constitution of the photoelectric conversion device may be simplified by using the conductive substrate as the rear surface junction electrode, generating an electricity flow from the semiconductor nanomaterial and metal layer that are joined by the schottky junction, and using the metal layer as the rear surface junction layer.

Further, in order to decrease a reflection ratio of incident light in a known art, a texturing process for forming pyramid type protrusions and depressions on a surface of a substrate is performed, but in the exemplary embodiment of the present invention, since a plurality of semiconductor nanomaterials vertically arranged have a texturing effect, a reflection ratio may be decreased without a separate texturing process.

That is, since a portion of incident light is absorbed on the surface of any one semiconductor nanomaterial, the residual portion is reflected, and the adjacent semiconductor nanomaterial is arranged in a reflection path of reflected light, light is reabsorbed on the adjacent semiconductor nanomaterial, such that the reflection ratio is remarkably decreased.

As described above, since the first exemplary embodiment and the second exemplary embodiment of the present invention may simplify the constitution of the photoelectric conversion device and remarkably decrease the reflection ratio, electrical energy generation efficiency may be improved.

The photoelectric conversion device using the semiconductor nanomaterial according to the first exemplary embodiment and the second exemplary embodiment of the present invention is manufactured by the following process.

First, the semiconductor nanomaterial layer 13 is formed by vertically arranging a plurality of semiconductor nanomaterials 13a, 13b, and 13c on a substrate 11.

In this case, the semiconductor nanomaterials 13a, 13b, and 13c may be formed by growing and arranging the nanomaterials through a chemical vapor deposition method (CVD) or a physical vapor deposition method (PVD) or an electrochemical method, or by arranging the previously synthesized semiconductor nanomaterial on the substrate 11.

Or, the semiconductor nanomaterials may be formed by arranging the nanomaterial grown by the chemical vapor deposition method (CVD), physical vapor deposition method (PVD), or an electrochemical method by a spin coating or printing method.

Or, the semiconductor nanomaterials may be formed by performing patterning through an imprint or etching process after arranging the nanomaterial grown by the nanomaterial growing method by a spin coating or printing method, or the nanostructure may be formed by etching the substrate having a semiconductor property.

Subsequently, the insulating layer is formed between the semiconductor nanomaterials 13a, 13b, and 13c so that the respective semiconductor nanomaterials are separated.

In this case, the insulating layer 12 may be applied with a method for exposing a portion of the upper portions of the semiconductor nanomaterials 13a, 13b, and 13c through an etching process after performing coating so that the upper portions of the semiconductor nanomaterials 13a, 13b, and 13c are exposed in a predetermined height or performing coating so that the semiconductor nanomaterial 13a, 13b, and 13c are completely buried.

Subsequently, the metal layer 14 is formed on the insulating layer 12 so that the metal layer 14 and the semiconductor nanomaterials 13a, 13b, and 13c are joined by the schottky junction.

These processes are the same as the first exemplary embodiment and the second exemplary embodiment, but in the second exemplary embodiment, a process for forming a front surface junction electrode 15 on the upper portion of the metal layer 14 is further performed.

Herein, the known photoelectric conversion device using the p-n junction performs N-type doping in the case where the P-type substrate is used, and performs P-type doping in the case where the N-type substrate is used, but in the exemplary embodiment of the present invention, since a separate doping process is not performed, the process may be shortened.

FIG. 7 is a cross-sectional view of a photoelectric conversion device using a semiconductor nanomaterial according to a third exemplary embodiment of the present invention, and the description with respect to the same constitution and an operation thereof as the first exemplary embodiment and the second exemplary embodiment of the present invention described above will be omitted.

Referring to FIG. 7, a photoelectric conversion device 2 of the third exemplary embodiment of the present invention includes a substrate 21, a semiconductor nanomaterial layer 22, an insulating layer 23, a metal layer 24 and a rear surface junction electrode 25.

Herein, the substrate 21 is a conductive substrate, and the semiconductor nanomaterial layer 22 is constituted by a plurality of semiconductor nanomaterials 22a horizontally arranged on the substrate 21. The substrate 21 may be formed of various kinds of metal such as aluminum that is joined with the nanomaterial layer 22 by an ohmic junction.

The insulating layer 23 may be formed of a transparent material having a large insulating coefficient such as SiOx and SiNx. The insulating layer 23 is formed in a thickness of 0.1 nm to 10 nm, and prevents recombination of carriers generated by light, such that a voltage characteristic is improved.

The nanomaterial layer 22 is formed of a semiconductor nanomaterial including a nanotube, a nanowire, and a nanoparticle. In this case, the nanoparticle may include a quantum point. Particularly, the semiconductor nanomaterials 22a may be formed of a nanowire, and may be formed of a silicon nanowire or a germanium nanowire.

The work function of the nanomaterial layer 22 may be controlled, and as the method for controlling the work function, a method using gas such as ammonia (NH₃) and oxygen, a method for performing reaction with a functional molecule such as potassium (K) and brome (Br) and heat treatment, a method using a connection chain with a polymer (PEI) material, and a method for doping metal such as aluminum may be applied.

Further, the metal layer 24 is joined with the semiconductor nanomaterial 22a by the schottky junction on the semiconductor nanomaterial layer 22, and electrical energy is generated by a rectification current generated between the semiconductor nanomaterial and the metal layer. The metal layer 24 may be formed of platinum or aluminum. In addition, the metal layer 24 may be made of a transparent conductive oxide (TCO) that can transmit light. In this case, the metal layer 24 may be formed of indium-tin-oxide (ITO), Al-doped zinc oxide (AZO), Zn-doped indium oxide (IZO), MgO, Nb:SrTiO3, Ga-doped ZnO (GZO), Nb-doped TiO2, (La0.5Sr0.5)CoO3 (LSCO), La0.7Sr0.3MnO3 (LSMO), SrRuO3 (SRO), F-doped tin oxide, Sr3Ru2O7, or Sr4Ru3O10.

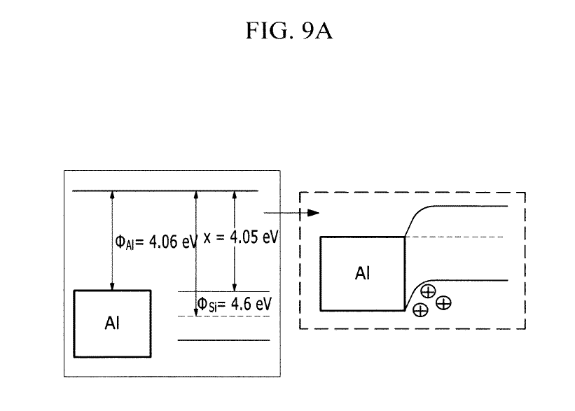

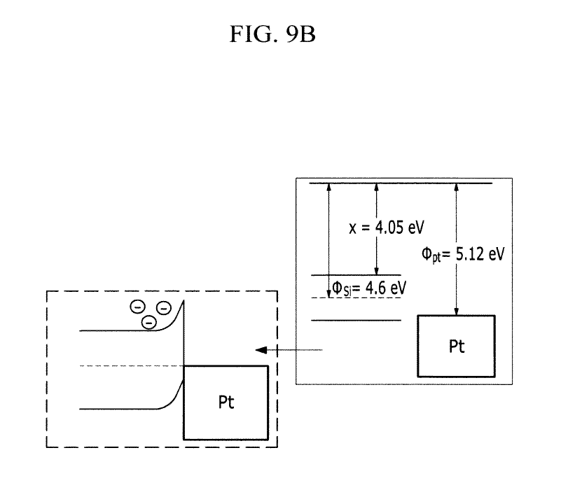

As shown in FIG. 9A and FIG. 9B, in the case where the metal layer 24 is formed of platinum, the substrate 21 is formed of aluminum, and the semiconductor nanomaterial 22a is formed of a silicon nanowire, the work function (Φ_{Si}) of the silicon nanowire is 4.6 eV, the work function (Φ_{Pt}) of platinum is 5.12 eV, and the work function (Φ_{At}) of aluminum is 4.06 eV. Further, electron affinity (x) of silicon is 4.05 eV.

As described above, if the metal layer 24 is joined with the nanomaterial layer 22 by the schottky junction, and the substrate 21 is joined with the nanomaterial 22 by the ohmic junction, the electrons are moved from the nanomaterial layer 22 to the metal layer 24, but the electrons cannot be moved in an opposite direction, such that a rectification operation is performed.

In addition, the metal layer 24 may act as the front surface junction electrode, or even though not shown in the drawing, the metal layer may further include a front surface junction electrode (not shown) that is formed of a metal material forming the ohmic junction with the metal layer on the upper portion of the metal layer 24.

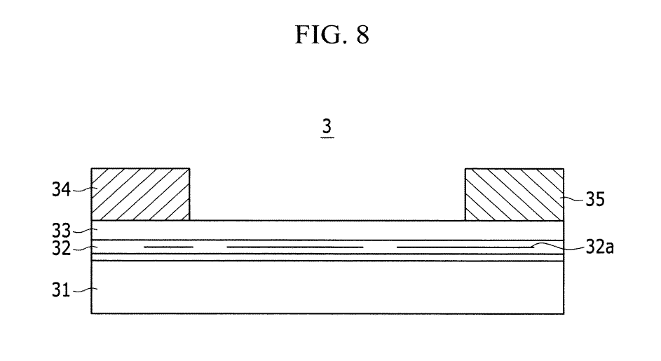

FIG. 8 is a cross-sectional view of a photoelectric conversion device 3 using a semiconductor nanomaterial according to a fourth exemplary embodiment of the present invention, and the description with respect to the same constitution and an operation thereof as the first exemplary embodiment and the third exemplary embodiment of the present invention described above will be omitted.

Referring to FIG. 8, a photoelectric conversion device 3 of the fourth exemplary embodiment of the present invention includes a substrate 31, a semiconductor nanomaterial layer 32, an insulating layer 33, a metal layer 34 and a junction electrode 35.

Herein, in the third exemplary embodiment described above, the junction electrode is provided on a lower portion of the substrate, but, in the fourth exemplary embodiment, the junction electrode 35 is provided on the upper portion of one side of the semiconductor nanomaterial layer 31.

The insulating layer 33 may be formed of a transparent material having a large insulating coefficient such as SiOx and SiNx. The insulating layer 33 is formed in a thickness of 0.1 nm to 10 nm, and prevents recombination of carriers generated by light, such that a voltage characteristic is improved.

The semiconductor nanomaterial layer 32 is formed of a semiconductor nanomaterial including a nanotube, a nanowire, and a nanoparticle. In this case, the nanoparticle may include a quantum point. Particularly, the nanomaterials 32a may be formed of a nanowire, and may be formed of a silicon nanowire or a germanium nanowire.

The work function of the semiconductor nanomaterial layer 32 may be controlled, and as the method for controlling the work function, a method using gas such as ammonia (NH₃) and oxygen, a method for performing reaction with a functional molecule such as potassium (K) and brome (Br) and heat treatment, a method using a connection chain with a polymer (PEI) material, and a method for doping metal such as aluminum may be applied.

Further, the metal layer 34 is joined with the semiconductor nanomaterial 32a by the schottky junction on the semiconductor nanomaterial layer 32, and electrical energy is generated by a rectification current generated between the semiconductor nanomaterial 32a and the metal layer 34. The metal layer 34 may be formed of platinum, or aluminum. In addition, the metal layer 34 may be made of a transparent conductive oxide (TCO) that can transmit light. In this case, the metal layer 34 may be formed of indium-tin-oxide (ITO), Al-doped zinc oxide (AZO), Zn-doped indium oxide (IZO), MgO, Nb:SrTiO3, Ga-doped ZnO (GZO), Nb-doped TiO2, (La0.5Sr0.5)CoO3 (LSCO), La0.7Sr0.3MnO3 (LSMO), SrRuO3 (SRO), F-doped tin oxide, Sr3Ru2O7, or Sr4Ru3O10.

The junction electrode 35 is formed of the metal material forming the ohmic junction with the semiconductor nanomaterial 32a. The junction electrode 35 may be formed of platinum, or aluminum. Further, the junction electrode 35 may be made of a transparent conductive oxide (TCO) that can transmit light. In this case, the metal layer 34 may be formed of indium-tin-oxide (ITO), Al-doped zinc oxide (AZO), Zn-doped indium oxide (IZO), MgO, Nb:SrTiO3, Ga-doped ZnO (GZO), Nb-doped TiO2, (La0.5Sr0.5)CoO3 (LSCO), La0.7Sr0.3MnO3 (LSMO), SrRuO3 (SRO), F-doped tin oxide, Sr3Ru2O7, and(or?) Sr4Ru3O10.

The substrate 21 is formed of a non-conductive substrate. Further, the substrate 21 may be formed of an opaque substrate, and a light transmissive substrate. In the case where the substrate 21 is formed of the light transmissive substrate, the substrate 21 may be formed of a transparent inorganic material such as quartz and glass, and a transparent polymer such as polyethylene terephalate (PET), polyethylene naphthalate (PEN), polyethylene sulfone (PES), polycarbonate, polystyrene, and polypropylene. In the case where the flexible substrate is used, a flexible schottky junction photoelectric conversion device may be manufactured.

In order to obtain a cell energy by an electron-hole flow between the semiconductor nanomaterial 33a and the metal layer 34, in the case where the N-type semiconductor nanomaterial is used, the work function of the semiconductor nanomaterial should be smaller than the work function of the metal layer 34, and in the case where the P-type semiconductor nanomaterial is used, the work function of the semiconductor nanomaterial 33a should be larger than the work function of the metal layer 34.

The photoelectric conversion device using the semiconductor nanomaterial according to the third exemplary embodiment and the fourth exemplary embodiment of the present invention is manufactured by the following process.

First, the semiconductor nanomaterial layer 31 is formed by horizontally arranging a plurality of semiconductor nanomaterials 32a on the substrate 31.

Herein, the semiconductor nanomaterial layer 31 may be formed by growing and arranging the nanomaterials through a chemical vapor deposition method (CVD) or a physical vapor deposition method (PVD) or an electrochemical method, or by arranging the previously synthesized semiconductor nanomaterial on the substrate 11.

Or, the semiconductor nanomaterials may be formed by arranging the nanomaterial grown by the chemical vapor deposition method (CVD), physical vapor deposition method (PVD), or electrochemical method by a spin coating or printing method.

Or, the semiconductor nanomaterials may be formed by, performing patterning through an imprint or etching process after arranging the nanomaterial grown by the nanomaterial growing method by a spin coating or printing method, or the nanostructure may be formed by etching the substrate having a semiconductor property.

Further, on the upper portion of the semiconductor nanomaterial layer 31, the insulating layer 33 is formed, and the metal layer is formed to be joined with the semiconductor nanomaterial 32a by the schottky junction.

In this case, in the drawing, the insulating layer 33 is shown, but the insulating layer may be omitted through other modified exemplary embodiments, and if necessary, in the case where the insulating layer 33 is formed, it is preferable that the insulating layer 33 is formed in a small thickness so that the semiconductor nanomaterial 32a is joined with the metal layer 34 by the schottky junction.

Further, in the third exemplary embodiment, the rear surface junction electrode 35 is formed on the lower portion of the substrate 31, and in the fourth exemplary embodiment, the rear surface junction electrode that is formed of the metal material joined with the semiconductor nanomaterial by the ohmic junction is further formed on the upper portion of one side of the semiconductor nanomaterial layer 31.

In addition, even though not shown in the drawing, the front surface junction electrode (not shown) that is formed of the metal material forming the ohmic junction with the metal layer may be further formed on the upper portion of the metal layer 34.

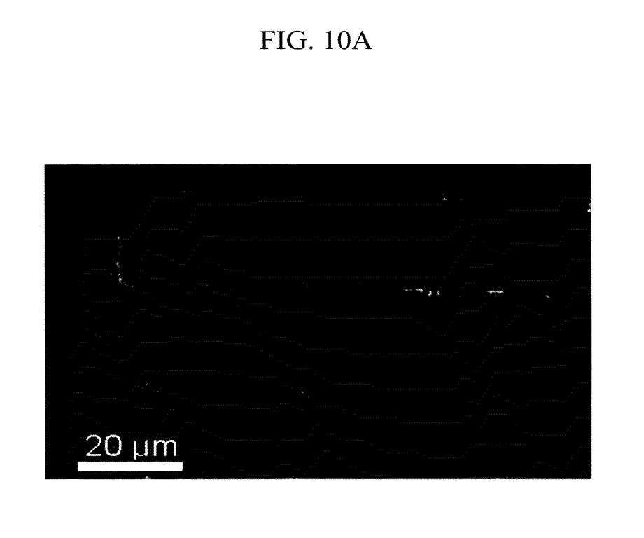

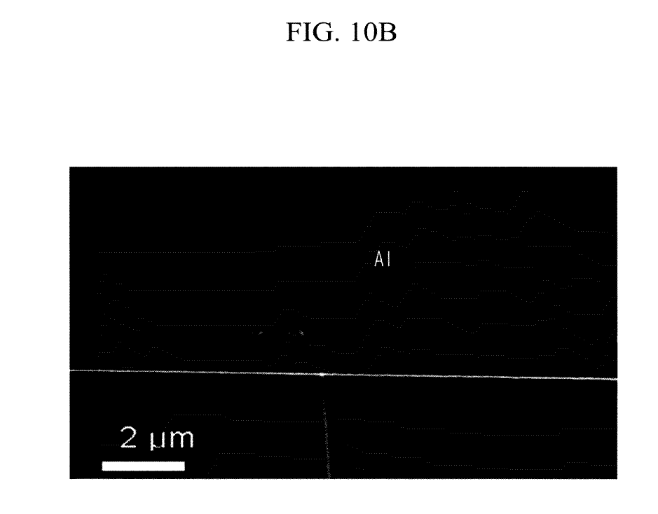

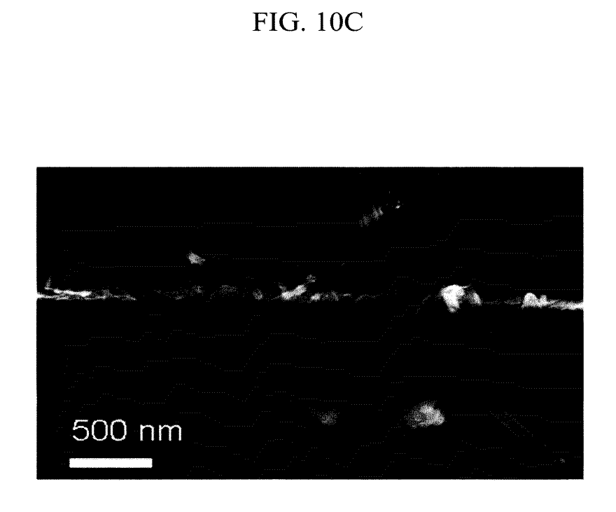

FIGS. 10A to 10c are pictures illustrating a photoelectric conversion device manufactured according to an exemplary variation of the fourth exemplary embodiment of the present invention.

The photoelectric conversion device according to the exemplary embodiment is formed of the same structure as the photoelectric conversion device according to the fourth exemplary embodiment, except that protrusions are formed on the metal layer and the junction electrode.

The metal layer and the junction electrode have a plurality of protrusions, and the protrusions of the junction electrode are disposed to be inserted between the protrusions of the metal layer. Further, the protrusions of the metal layer and the protrusions of the junction electrode are separated from each other.

In the exemplary embodiment, on the semiconductor nanomaterial layer including the silicon nanowire, the metal layer formed of platinum and the junction electrode formed of aluminum are formed. Referring to FIGS. 10A to 10c, the metal layer and the junction electrode having the protrusions are separated, and the metal layer and the junction electrode are electrically connected by the silicon nanowire.

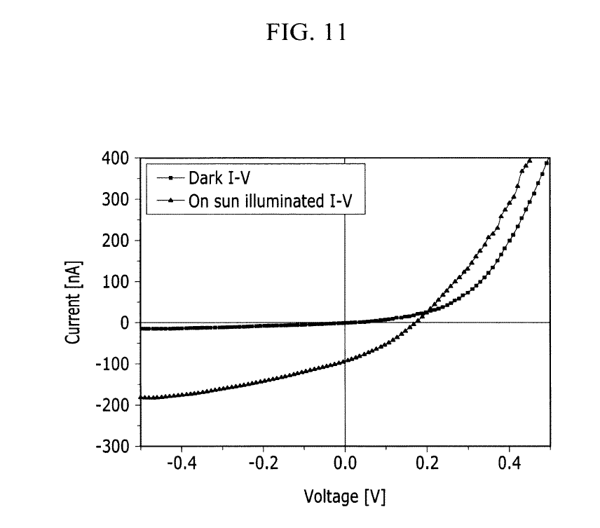

FIG. 11 is a current voltage diagram of the photoelectric conversion device according to the exemplary variation of the fourth exemplary embodiment of the present invention, and as shown in FIG. 11, from the current voltage diagram according to the exemplary embodiment, it can be seen that a rectification is apparently performed in a dark room state in which there is no light and electric power is generated in a light room state in which there is light.

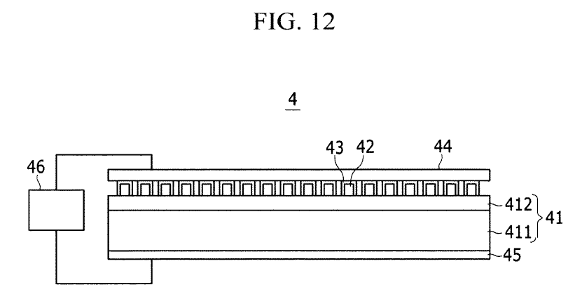

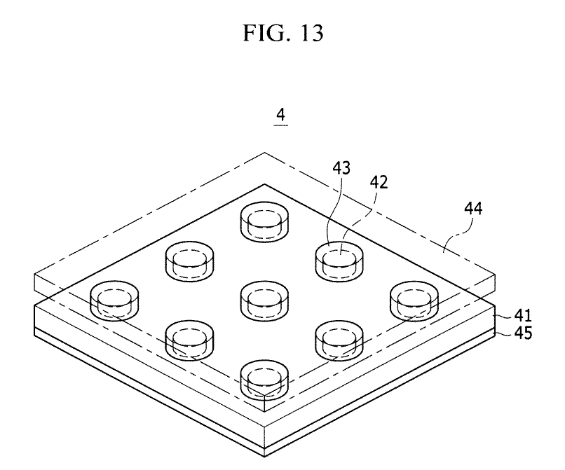

FIG. 12 is a cross-sectional view of a photoelectric conversion device according to a fifth exemplary embodiment of the present invention and FIG. 13 is a perspective view illustrating the photoelectric conversion device according to the fifth exemplary embodiment of the present invention.

Referring to FIG. 12 and FIG. 13, the photoelectric conversion device 4 according to the exemplary embodiment includes a substrate 41, a semiconductor nanoprotrusion 42 formed on the substrate 41, a transparent metal film 43 covering the semiconductor nanoprotrusion 42, and a front surface electrode 44 formed on the transparent metal film 43. Herein, the semiconductor nanoprotrusion 42 becomes the semiconductor nanomaterial, and the transparent metal film 43 becomes the metal layer that is joined with the semiconductor nanomaterial by the schottky junction.

The substrate 41 is formed in a silicon crystalline wafer type, and includes a P-type semiconductor layer 411 and an N-type semiconductor layer 412. The substrate 41 is formed of crystalline silicon, and the substrate 41 may be obtained by doping the N-type material to P-type crystalline silicon. However, the present invention is not limited thereto, and the substrate 41 may be formed of GaAs, InP, InGaP, CdSe, CdS, ZnSe, ZnS, or ZnTe in addition to silicon.

The rear surface electrode 45 is formed on the rear surface of the substrate 41, and the rear surface electrode 45 may be formed of silver or aluminum that is a conductive metal.

The front surface electrode 44 is formed of the transparent conductive material, and particularly, the front surface electrode 44 may be formed of the transparent conductive oxide (TCO). Herein, the transparent conductive oxide may be formed of indium-tin-oxide (ITO), Al-doped zinc oxide (AZO), Zn-doped indium oxide (IZO), MgO, Nb:SrTiO3, Ga-doped ZnO (GZO), Nb-doped TiO2, (La0.5Sr0.5)CoO3 (LSCO), La0.7Sr0.3MnO3 (LSMO), SrRuO3 (SRO), F-doped tin oxide, Sr3Ru2O7, or Sr4Ru3O10.

Particularly, the front surface electrode 44 may be formed of AZO, and in this case, AZO may be formed by a co-sputtering method in which Al and ZnO are supplied together. A power device 46 for accumulating electricity is connected to the front surface electrode 44 and the rear surface electrode 45.

Between the front surface electrode 44 and the substrate 41, a plurality of semiconductor nanoprotrusions 42 protrude, and the semiconductor nanoprotrusions 42 are formed by etching the N-type semiconductor layer 412 by a method such as plasma etching. Accordingly, the semiconductor nanoprotrusions 42 have an N-type semiconductor characteristic. The semiconductor nanoprotrusions 42 are regularly or irregularly arranged in plural on the substrate 41 at intervals.

As shown in the exemplary embodiment, if the semiconductor nanoprotrusion 42 is formed on the substrate 41, the surface area of the substrate 41 is increased, such that the absorption of light expands to improve photoelectric efficiency. Accordingly, a current characteristic of the photoelectric conversion device is improved.

The transparent metal film 43 is formed of metal that is joined with the semiconductor nanoprotrusion 42 by the schottky junction. Accordingly, the transparent metal film 43 is formed of a material having a larger work function than the nanoprotrusion. The transparent metal film is formed of the transparent conductive material, and particularly, may be formed of transparent conductive oxide (TCO). Herein, transparent conductive oxide may be formed of indium-tin-oxide (ITO), Al-doped zinc oxide (AZO), or Zn-doped indium oxide (IZO).

If the semiconductor nanoprotrusion 42 and the transparent metal film 43 are joined by the schottky junction, a potential difference is formed even between the semiconductor nanoprotrusion 42 and the transparent metal film 43, such that voltage may be increased as compared to a known wafer type photoelectric conversion device.

That is, holes generated when light is incident are collected in the semiconductor nanoprotrusion 42 and electrons are collected in the transparent metal film 43, such that voltage occurs at an interface between the semiconductor nanoprotrusion 42 and the transparent metal film 43.

The transparent metal film 43 is formed to cover the semiconductor nanoprotrusion 42, and is formed to cover an upper surface and a lateral surface of the semiconductor nanoprotrusion 42. The transparent metal film 43 may be formed by a method such as sputtering and deposition. Particularly, the transparent metal film 43 may be formed by allowing the front surface electrode 44 to permeate between the semiconductor nanoprotrusions 42 in the course of forming the front surface electrode 44. In the course of forming the front surface electrode 44, if a deposition speed of AZO is decreased, the transparent metal film 43 may be formed by allowing the front surface electrode 44 to permeate between the semiconductor nanoprotrusions 42.

However, the present invention is not limited thereto, but the transparent metal film 43 may be formed by a process that is different from the process for forming the front surface electrode.

The reflection ratio of the transparent metal film 43 is smaller than the reflection ratio of the substrate 41, and is larger than the reflection ratio of air. In the case where the transparent metal film 43 is formed of AZO, a refractive index of the transparent metal film 43 is 2.4 that is a value between a refractive index of air (n=1) and a refractive index of the substrate 41 formed of silicon (n=4.1). If the refractive index of the transparent metal film 43 has a value between the refractive index of air and the refractive index of silicon, reflection of light incident on the substrate 41 may be decreased.

As described above, if the reflection of light is decreased, the photoelectric efficiency is improved, such that a current characteristic of the photoelectric conversion device is improved.

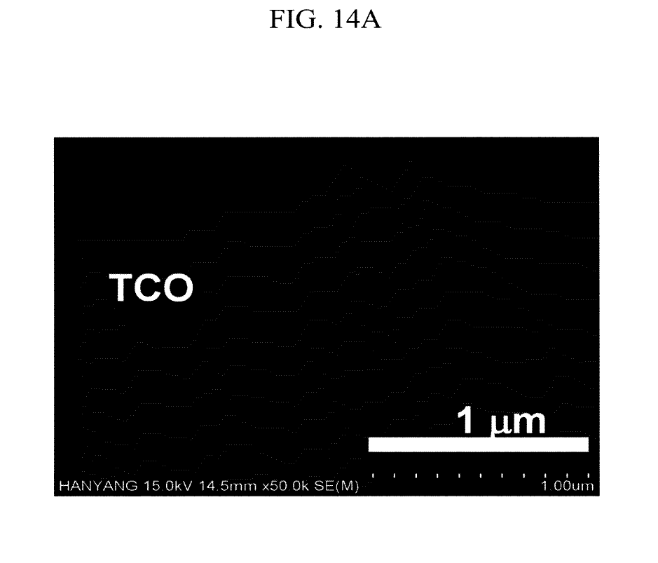

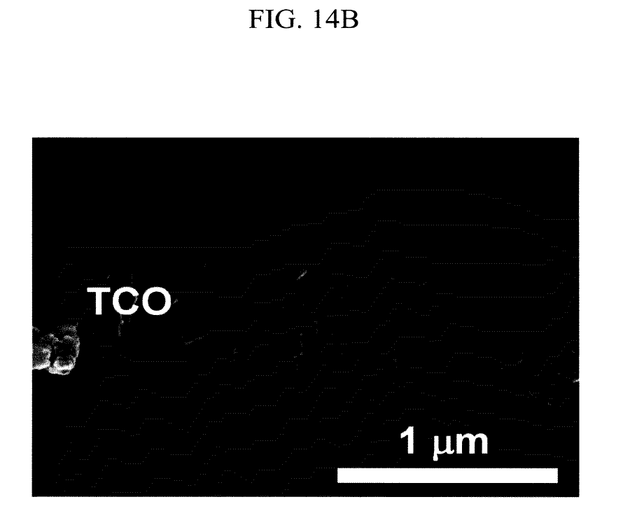

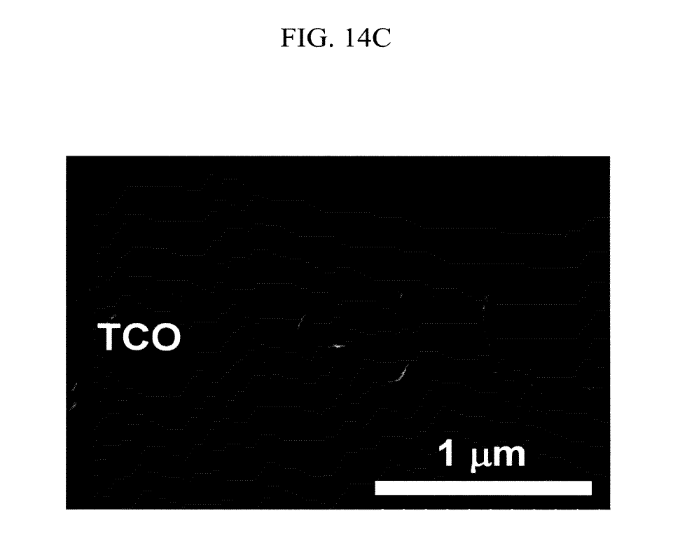

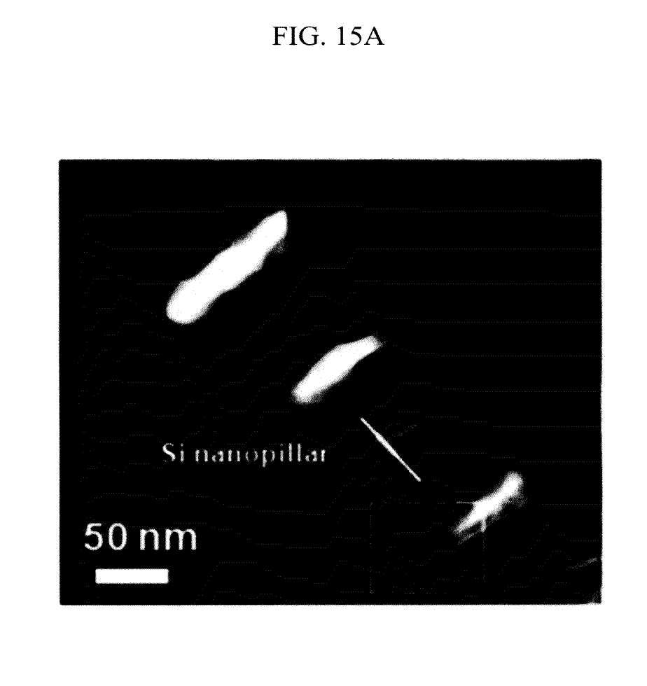

FIG. 14A is a picture illustrating that a transparent electrode is formed on a silicon wafer, FIG. 14B is a picture illustrating that a transparent metal film and the transparent electrode are formed on a low density nanoprotrusion, and FIG. 14C is a picture illustrating that the transparent metal film and the transparent electrode are formed on a high density nanoprotrusion.

Referring to FIG. 14C, the transparent metal film 43 that is formed of AZO is formed on an external wall of the semiconductor nanoprotrusion 42, and the front surface electrode 44 that is formed of AZO is formed on the transparent metal film 43. A portion in which the transparent metal film 43 is formed is thicker than other portions.

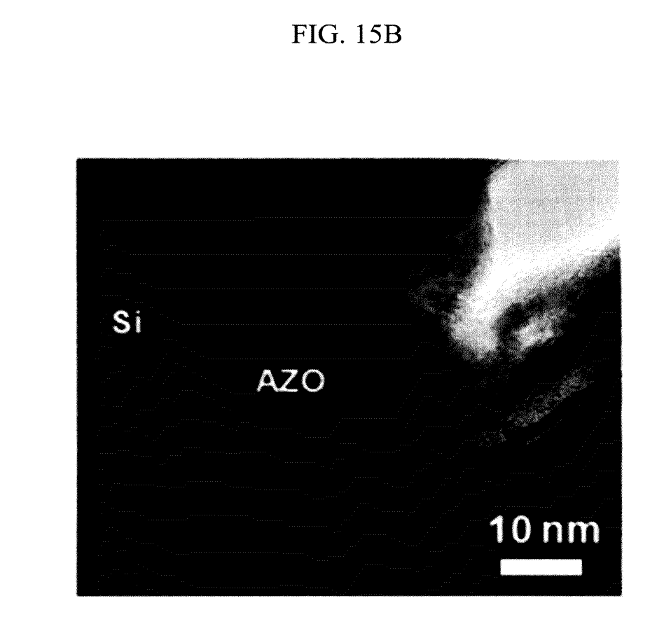

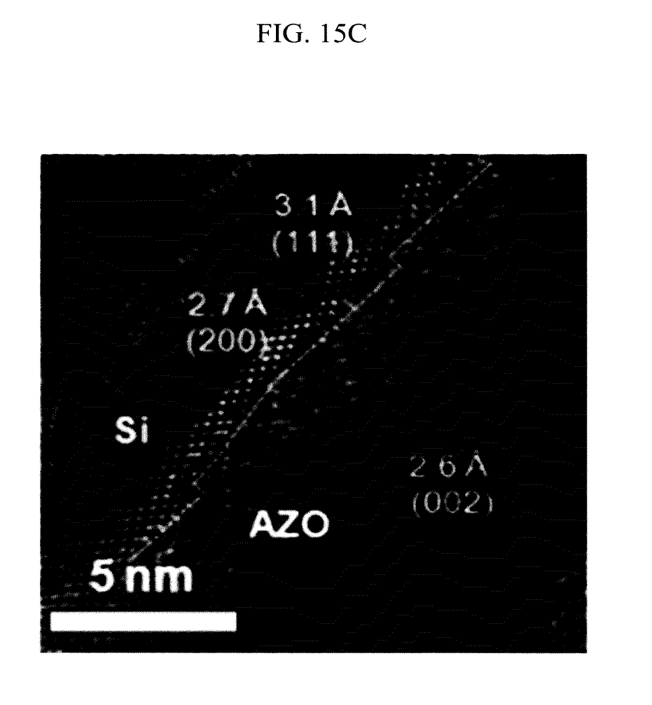

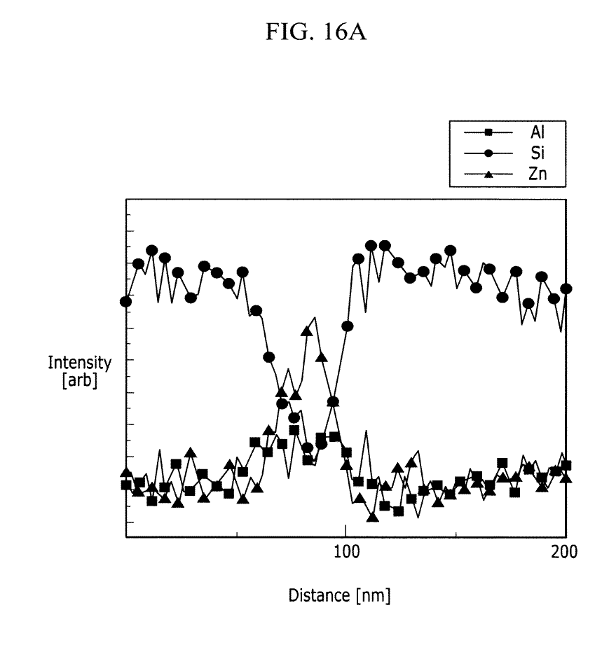

FIG. 15A is a cross-sectional view obtained by cutting the photoelectric conversion device according to the first exemplary embodiment of the present invention in a length direction, FIG. 15B is a picture in which an inside of a quadrangle in FIG. 15A is enlarged, and FIG. 15C is a picture in which an interface between the nanoprotrusion and the transparent metal film is enlarged.

As shown in FIG. 15A and FIG. 15B, it can be apparently seen that the transparent metal film 43 that is formed of AZO is formed on an external surface of the semiconductor nanoprotrusion 42.

Further, as shown in FIG. 15C, it can be apparently seen that the transparent metal film that is formed of AZO along a 002 plane surface is formed in a lattice space of 0.26 nm.

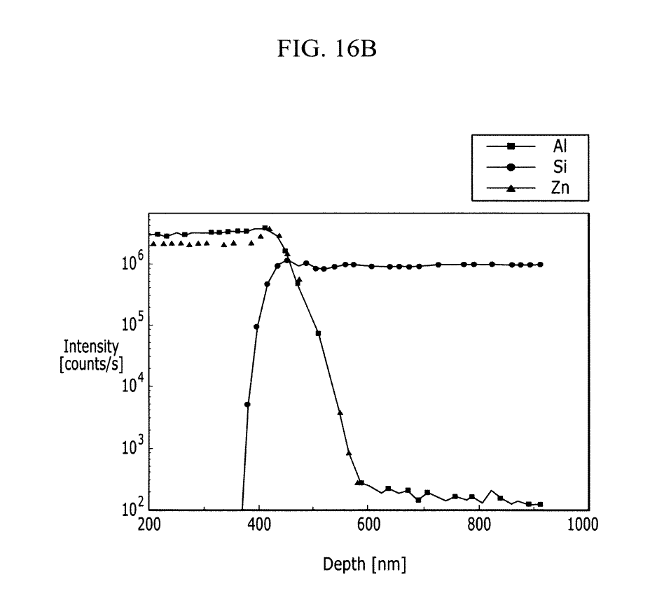

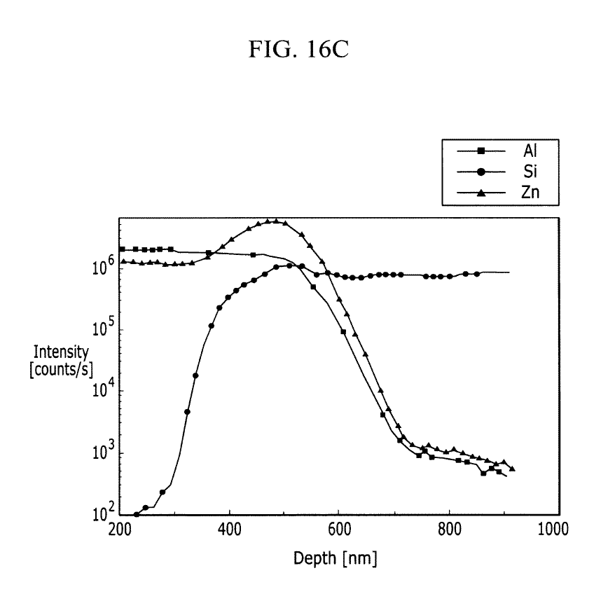

FIG. 16A is a graph illustrating a component profile between the nanoprotrusions in a horizontal direction with respect to an upper surface of a silicon wafer according to the first exemplary embodiment of the present invention, FIG. 16B is a graph illustrating a component profile in a depth direction of the silicon wafer according to the first exemplary embodiment of the present invention, and FIG. 16C is a graph illustrating a component profile in a depth direction of the silicon wafer in a state in which an AZO electrode is formed on a flat wafer.

As shown in FIG. 16A, it can be seen that a groove in which a silicon component is low is formed between the nanoprotrusions in which the silicon component is high, and that the transparent metal film is formed in the groove, such that a Zn component is high.

As shown in FIG. 16B, according to the exemplary embodiment, it can be seen that the transparent metal film 43 is formed, such that a large amount of Zn exist in a depth of 600 nm, but as shown in FIG. 16C, in the case where the transparent metal film 43 is not formed, it can be seen that Zn hardly exists in a depth of 600 nm.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A photoelectric conversion device using a semiconductor nanomaterial, which converts light energy having photon energy into electrical energy, comprising:
a substrate,
a plurality of semiconductor nanomaterials arranged on the substrate, and
a metal layer that is formed on the semiconductor nanomaterial and is joined with the semiconductor nanomaterial by a schottky junction,
wherein electrical energy is generated by a rectified current generated between the semiconductor nanomaterial and the metal layer joined by the schottky junction.

2. The photoelectric conversion device using a semiconductor nanomaterial of claim 1, wherein:
insulating layers are formed on the substrate, and the semiconductor nanomaterial is arranged between the insulating layers.

3. The photoelectric conversion device using a semiconductor nanomaterial of claim 1, wherein:
a nanomaterial layer in which the semiconductor nanomaterials are horizontally arranged is formed between the substrate and the metal layer.

4. The photoelectric conversion device using a semiconductor nanomaterial of claim 3, wherein:
an insulating layer for preventing a carrier generated by light from being recombined is formed between the nanomaterial layer and the metal layer.

5. The photoelectric conversion device using a semiconductor nanomaterial of claim 1, wherein:
the substrate is formed of a conductive substrate and is used as a rear surface junction electrode.

6. The photoelectric conversion device using a semiconductor nanomaterial of claim 1, wherein:
a junction electrode that is formed of a metal material forming an ohmic junction with the semiconductor nanomaterial is formed on an upper portion of one side of the semiconductor nanomaterial, and
the junction electrode and the metal layer are arranged side by side.

7. The photoelectric conversion device using a semiconductor nanomaterial of claim 5, wherein:
the metal layer is formed of platinum, the junction electrode is formed of aluminum, and the semiconductor nanomaterial is formed of a nanowire.

8. The photoelectric conversion device using a semiconductor nanomaterial of claim 1, wherein:
the metal layer is formed of a transparent conductive oxide.

9. The photoelectric conversion device using a semiconductor nanomaterial of claim 1, wherein:
the semiconductor nanomaterial is formed of a semiconductor nanoprotrusion, and the metal layer is formed of a transparent metal film covering the semiconductor nanoprotrusion.

10. The photoelectric conversion device using a semiconductor nanomaterial of claim 9, wherein:
the substrate has a P-type semiconductor layer and an N-type semiconductor layer joined with the P-type semiconductor layer by a PN junction.

11. The photoelectric conversion device using a semiconductor nanomaterial of claim 10, wherein:
the semiconductor nanoprotrusion is formed by etching the substrate.

12. The photoelectric conversion device using a semiconductor nanomaterial of claim 9, wherein:
a front surface electrode formed of the transparent conductive oxide is formed on the semiconductor nanoprotrusion.

13. The photoelectric conversion device using a semiconductor nanomaterial of claim 1, wherein:
the semiconductor nanomaterial is an N-type semiconductor, and a work function of the semiconductor nanomaterial is smaller than a work function of the metal layer.

14. The photoelectric conversion device using a semiconductor nanomaterial of claim 1, wherein:
the semiconductor nanomaterial is a P-type semiconductor, and a work function of the semiconductor nanomaterial is larger than a work function of the metal layer.
